(19) United States
(12) Patent Application Publication
(10) Pub. No.: US 2026/0362944 A1
(43) Pub. Date: Nov. 12, 2026

(54) ELECTRONIC DEVICE AND METHOD OF MANUFACTURING THE SAME

(71) Applicants: Samsung Display Co., Ltd., Yongin-si (KR); Gwangju Institute Of Science And Technology, Buk-gu (KR)

(72) Inventors: Jooho Yun, Yongin-si (KR); Youngmin Song, Gwangju (KR); Heeyoung Lee, Yongin-si (KR); Hyukjae Jang, Gwangju (KR); Sungguk An, Yongin-si (KR); Jaemin Jeon, Gwangju (KR)

(21) Appl. No.: 19/665,532

(22) Filed: May 1, 2026

(30) Foreign Application Priority Data
May 7, 2025 (KR) 10-2025-0059254

(51) Int. Cl. H10K 59/80; H10K 59/12; H10K 102/00

(52) U.S. Cl. CPC H10K 59/871; H10K 59/1201; H10K 2102/351

(57) ABSTRACT

Provided is an electronic device including a display panel including a light-emitting diode, a cover film on the display panel and including a first protrusion pattern on a first surface and a second protrusion pattern on a second surface opposite to the first surface, a first coating on the first surface of the cover film in accordance with a shape of the first protrusion pattern, and a second coating on the second surface of the cover film in accordance with a shape of the second protrusion pattern.

### CROSS-REFERENCE TO RELATED APPLICATION

The present application claims priority to and the benefit of Korean Patent Application No. 10-2025-0059254, filed on May 7, 2025, in the Korean Intellectual Property Office, the entire content of which is incorporated herein by reference.

### BACKGROUND

### 1. Field

One or more embodiments of the present disclosure relate to an electronic device and a method of manufacturing the same. An electronic device according to the disclosure may include a display panel and a coating element that covers the display panel.

### 2. Description of the Related Art

Electronic devices may display video and/or images by using display panels provided therein. Display panels may display video and/or images by emitting light from light-emitting diodes provided therein. Applications of display panels have diversified in recent years, and various functions that are applied or linked to display panels have been proposed. Electronic devices may include a coating element, such as a film, that protects a display panel from external factors such as air and/or impacts.

### SUMMARY

A display panel and a coating element may be bonded together via an adhesive layer. The coating element and the atmosphere outside the coating element may have different refractive indices. The coating element and the adhesive layer in contact with the coating element may have different refractive indices. If (e.g., when) a difference between these different refractive indices is sufficiently large, reflection (e.g., of external light) may occur at an interface between layers having different refractive indices. Because the display panel displays a video and/or an image by emitting light via a light-emitting diode provided in the display panel, if (e.g., when) the above-described reflected external light is also visible to a user, the overall display quality of the display panel may deteriorate. Therefore, a structure capable of reducing reflection of such external light may be required or desired.

Additional aspects of embodiments will be set forth in part in the description which follows and, in part, will be apparent from the description, or may be learned by practice of the presented embodiments of the disclosure.

One or more embodiments include an electronic device including a display panel including a light-emitting diode, a cover film on the display panel and including a first protrusion pattern on a first surface and a second protrusion pattern on a second surface opposite to the first surface, a first coating on the first surface of the cover film in accordance with (e.g., corresponding to) a shape of the first protrusion pattern, and a second coating on the second surface of the cover film in accordance with (e.g., corresponding to) a shape of the second protrusion pattern.

The electronic device may further include a third coating on the first coating and including a different material from a material included in the first coating.

The electronic device may further include an adhesive layer between the display panel and the second coating, and a refractive index of the second coating may be between a refractive index of the cover film and a refractive index of the adhesive layer.

The first coating may have a thickness of about 30 nanometers to about 50 nanometers.

The second coating may have a thickness of about 20 nanometers to about 50 nanometers.

At least one of the first protrusion pattern and the second protrusion pattern may have a height of about 200 nanometers to about 400 nanometers.

The cover film may have a thickness of about 50 micrometers to about 200 micrometers.

At least one selected from the first protrusion pattern and the second protrusion pattern may have a plurality of parabolas, as viewed in a cross-section.

A width of a lowermost portion of a first parabola among the plurality of parabolas of the first protrusion pattern or the second protrusion pattern may be about 40% to about 100% of a distance between a peak of the first parabola and a peak of a second parabola adjacent to the first parabola.

The first protrusion pattern and the second protrusion pattern may have same shapes as each other.

One or more embodiments include an electronic device including a display panel including a light-emitting diode, a cover film on the display panel, a first coating on the cover film, a second coating between the cover film and the display panel, and an adhesive layer between the second coating and the display panel. A refractive index of the second coating is between a refractive index of the cover film and a refractive index of the adhesive layer.

One or more embodiments include a method of manufacturing an electronic device, the method including forming a coating element, and combining the coating element with a display panel including a light-emitting diode. The forming of the coating element includes forming a first protrusion pattern on a first surface of a cover film, forming a second protrusion pattern on a second surface opposite to the first surface of the cover film, forming a first coating on the first surface of the cover film, the first coating having a shape corresponding to the first protrusion pattern, and forming a second coating on the second surface of the cover film, the second coating having a shape corresponding to the second protrusion pattern.

The method may further include forming a third coating on the first coating, the third coating including a different material from a material included in the first coating.

At least one selected from the forming of the first protrusion pattern and the forming of the second protrusion pattern may include molding.

The forming of the first protrusion pattern and the forming of the second protrusion pattern may be performed concurrently (e.g., simultaneously).

The forming of the first coating may include performing atomic layer deposition, and the forming of the second coating may include performing chemical vapor deposition.

The combining of the display panel with the coating element may include providing an adhesive layer between the display panel and the second coating, and a refractive index of the second coating may be between a refractive index of the cover film and a refractive index of the adhesive layer.

At least one selected from the first protrusion pattern and the second protrusion pattern may have a plurality of parabolas, as viewed in a cross-section.

A width of a lowermost portion of a first parabola among the plurality of parabolas of the first protrusion pattern or the second protrusion pattern may be about 40% to about 100% of a distance between a peak of the first parabola and a peak of a second parabola adjacent to the first parabola.

At least one of the plurality of parabolas may have a height of about 200 nanometers to about 400 nanometers.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a block diagram of an electronic device according to an embodiment;

FIGS. 2-4 are schematic views of electronic devices according to several embodiments;

FIG. 5 is a schematic cross-sectional view of an electronic device according to an embodiment;

FIG. 6 is a schematic plan view of a display panel according to an embodiment;

FIG. 7 is an equivalent circuit diagram of a pixel of a display panel according to an embodiment;

FIG. 8 is a cross-sectional view of a display area of a display panel according to an embodiment;

FIG. 9 is a cross-sectional view of a coating element according to an embodiment;

FIG. 10 is a magnified cross-sectional view of a cover film according to an embodiment;

FIG. 11 is a plan view of a cover film according to an embodiment;

FIG. 12 is a magnified cross-sectional view of a cover film according to an embodiment;

FIG. 13 is a bottom view of a cover film according to an embodiment;

FIG. 14 is a cross-sectional view of a coating element according to an embodiment;

FIG. 15 is a cross-sectional view of a coating element according to an embodiment;

FIG. 16 is a cross-sectional view of a coating element according to an embodiment; and

FIGS. 17A-17H are cross-sectional views illustrating a method of manufacturing an electronic device, according to an embodiment.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

As the disclosure allows for various suitable changes and numerous embodiments, example embodiments will be illustrated in the drawings and described in more detail in the written description. Hereinafter, effects and features of embodiments of the disclosure and a method to accomplish them will be described more fully with reference to the accompanying drawings, in which embodiments of the disclosure are shown. The subject matter of the disclosure may be embodied in many different forms and should not be construed as limited to the embodiments set forth herein.

One or more embodiments will be described below in more detail with reference to the accompanying drawings. Those components that are the same as or are in correspondence with each other are rendered the same reference numeral regardless of the figure number, and redundant explanations are omitted.

It will be understood that although the terms "first," "second," and/or the like may be used herein to describe various components, these components should not be limited by these terms. These components are only used to distinguish one component from another.

As used herein, the singular forms "a," "an," and "the" are intended to include the plural forms as well, unless the context clearly indicates otherwise.

It will be further understood that the terms "comprises" and/or "comprising" used herein specify the presence of stated features or components, but do not preclude the presence or addition of one or more other features or components.

If (e.g., when) a layer, region, or component is referred to as being "formed on" another layer, region, or component, it can be directly or indirectly formed on the other layer, region, or component. For example, intervening layers, regions, or components may be present.

Sizes of elements in the drawings may be exaggerated or reduced for convenience of explanation. For example, because sizes and thicknesses of components in the drawings may be arbitrarily illustrated for convenience of explanation, embodiments are not limited thereto.

If (e.g., when) a certain embodiment may be implemented differently, a specific process order may be performed differently from the described order. For example, two consecutively described processes may be performed substantially at the same time or performed in an order opposite to the described order.

The expression "A and/or B" indicates A or B, or A and B. The expression "at least one of A or B" indicates only A, only B, both A and B, or variations thereof.

If (e.g., when) a layer, region, or component is referred to as being (e.g., electrically) "connected" or "coupled" to another layer, region, or component, it may be directly (e.g., electrically) connected or coupled to the other layer, region, or component or/and intervening layers, regions, or components may be present and thus the layer, region, or component may be indirectly (e.g., electrically) connected or coupled to the other layer, region, or component.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may not be perpendicular to one another.

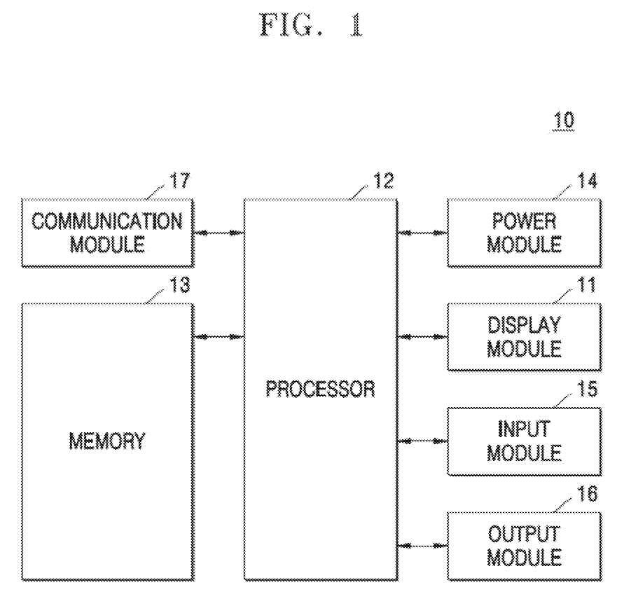

FIG. 1 is a block diagram of an electronic device 10 according to an embodiment. Referring to FIG. 1, the electronic device 10 may include a display panel 11, a processor 12, memory 13, and a power module 14.

The processor 12 may include at least one selected from a central processing unit (CPU), an application processor (AP), a graphics processing unit (GPU), a communication processor (CP), an image signal processor (ISP), and a controller. According to an embodiment, the processor 12 may include two or more processors divided by functional or structural aspects. For example, the processor 12 may include a main processor in the form of a first drive chip including a CPU, and an auxiliary processor in the form of a second drive chip including a controller that receives an image signal from the main processor and processes the image signal to conform to the interface specifications of the display panel 11.

The memory 13 may include at least one selected from a non-volatile memory and a volatile memory. The memory 13 may store data information necessary or useful for an operation of the processor 12 and/or the display panel 11. If (e.g., when) the processor 12 executes an application stored in the memory 13, an image data signal and/or an input control signal may be transmitted to the display panel 11, and the display panel 11 may process the received signal and output image information through a display screen.

The power module 14 may include a power supply module, such as a power adapter and/or a battery device, and a power conversion module that converts power supplied by the power supply module to generate power necessary or useful for an operation of the electronic device 10. Power conversion by the power conversion module may include, but is not necessarily limited to, direct current (DC)-to-DC conversion, alternating current (AC)-to-DC conversion, and DC-to-AC conversion.

The electronic device 10 may further include an input module 15, a non-image output module16, and/or a communication module 17.

The input module 15 may provide input information to the processor 12 and/or the display panel 11. The input module 15 may include various suitable sensor modules as well as physical buttons, a keyboard, and/or a microphone. Examples of the sensor modules may include a touch sensor, a pressure sensor, a distance sensor, a position sensor, a digitizer, a motion recognition sensor, a camera sensor, a light-receiving sensor, a photoelectric conversion sensor, and a temperature sensor, as well as biosensors, such as a blood pressure sensor, a blood sugar sensor, an electrocardiogram sensor, and a heart rate sensor.

The non-image output module 16 may receive information other than an image received from the processor 12, and may provide the information to a user. Examples of the non-image output module 16 may include a sound module, a haptic module, a light-emitting module, and may include other functional modules designed for or unique to a set or specific electronic device (e.g., a cooling module of a refrigerator).

The communication module 17, which is a module responsible to transmit and receive information between the electronic device 10 and an external device, may include a reception unit and a transmission unit. The communication module 17 may include various suitable wireless communication modules, such as a mobile communication module, a Wi-Fi module, and a Bluetooth module, or various suitable wired communication modules.

At least one of the components of the electronic device 10 described above may be included in a display apparatus. In embodiments, some of the individual modules functionally included within a module may be included within a display apparatus, and the others may be provided separately from the display apparatus. For example, the display apparatus may include the display panel 11, and the processor 12, the memory 13, and the power module 14 may be provided in the form of other devices within the electronic device 10 rather than the display apparatus. As another example, the power module 14 may be provided within the display apparatus, and may supply power to the processor 12 and the memory 13 provided within the electronic device 10 other than the display apparatus. However, embodiments are not limited to the above examples.

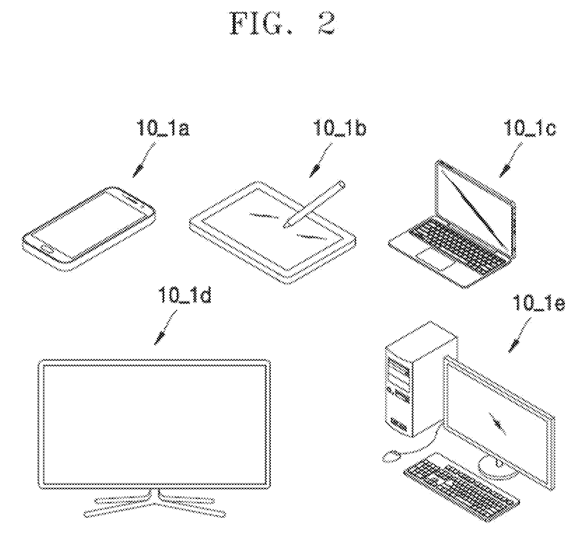

FIGS. 2-4 are schematic views of electronic devices according to several embodiments. FIGS. 2-4 illustrate various suitable electronic devices to which display apparatuses according to embodiments may be applied.

FIG. 2 illustrates, as examples of electronic devices, a smartphone 10_1a, a tablet personal computer (PC) 10_1b, a laptop 10_1c, a TV 10_1d, and a computer monitor 10_1e.

The smartphone 10_1a may include an input module, such as a touch sensor, and a communication module, in addition to a display panel. The smartphone 10_1a may process information received through the communication module or other input modules, and may display the information through the display panel of the display apparatus.

Even the tablet PC 10_1b, the laptop 10_1c, the TV 10_1d, and the desk monitor 10_1e may include a display panel and an input module, similar to the smartphone 10_1a. In some embodiments, the tablet PC 10_1b, the laptop 10_1c, the TV 10_1d, and the desk monitor 10_1e may further include communication modules.

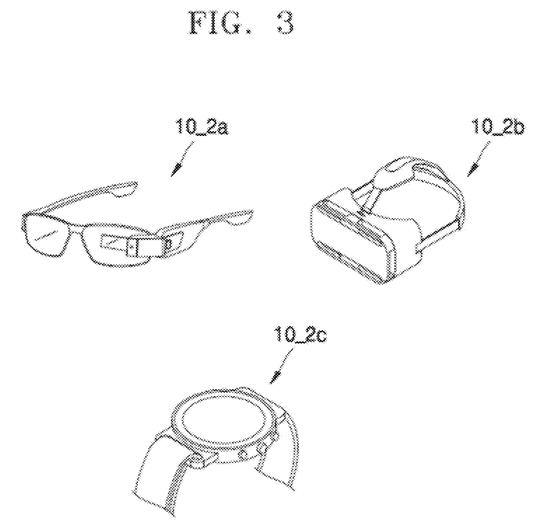

FIG. 3 illustrates an embodiment where an electronic device including a display panel is applied to a wearable electronic device. The wearable electronic device may be smart glasses 10_2a, a head mounted display 10_2b, a smart watch 10_2c, and/or the like.

The smart glasses 10_2a and the head mounted display 10_2b may include a display panel to emit a display image and a reflector to reflect the emitted display image to provide a result of the reflection to the user's eyes, thereby providing a virtual reality and/or augmented reality screen image to the user.

The smartwatch 10_2c may include a biosensor as an input device, and may provide biometric information recognized by the biosensor to the user through a display panel.

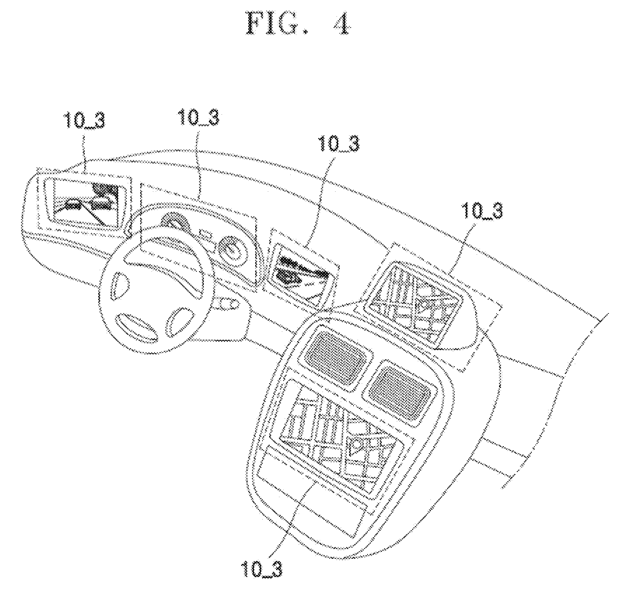

FIG. 4 illustrates a case where an electronic device including a display panel is applied to a vehicle. For example, an electronic device 10_3 may be applied to dashboards, center fasciae, and/or the like of automobiles, or may be applied to, for example, center information displays (CIDs) on the dashboards of automobiles and/or room mirror displays that replace the side mirrors of automobiles.

In embodiments, electronic devices to which display apparatuses according to embodiments are applied may include not only devices that mainly perform screen display, such as a billboard, an electronic board, and a game console, but also various suitable home appliances that display information through display panels, such as a refrigerator, a washing machine, a dryer, an air conditioner, and a robot vacuum cleaner. In embodiments, if (e.g., when) a display panel has a function of transmitting light, the display panel may be applied to electronic devices, such as smart windows and/or transparent display apparatuses that display both a background and a displayed image. The types or kinds of electronic devices according to embodiments are not limited to those exemplified above, and application of various other suitable electronic devices is also possible.

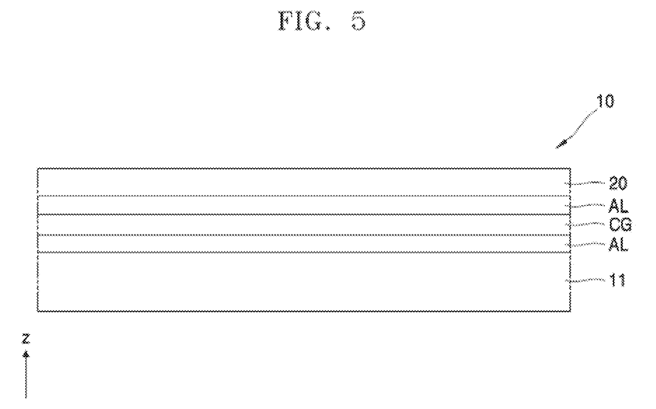

FIG. 5 is a schematic cross-sectional view of an electronic device according to an embodiment.

Referring to FIG. 5, the electronic device 10 may include the display panel 11, a cover glass CG on the display panel 11, and a coating element 20 on the cover glass CG. The cover glass CG and the coating element 20 may be on the display panel 11 to protect the display panel 11 from external impact, and may prevent or reduce infiltration of foreign substances, such as external air and/or moisture, into the display panel 11.

According to an embodiment, an adhesive layer AL may be between the cover glass CG and the display panel 11. According to an embodiment, the cover glass CG and the display panel 11 may be coupled to each other via the adhesive layer AL. According to an embodiment, an adhesive layer AL may be between the cover glass CG and the coating element 20. According to an embodiment, the cover glass CG and the coating element 20 may be coupled to each other via the adhesive layer AL.

According to an embodiment, the adhesive layer AL may include an optically clear adhesive (OCA). According to an embodiment, the adhesive layer AL may be on the display panel 11 in the form of a film, and the cover glass CG may be on the adhesive layer AL. According to an embodiment, the adhesive layer AL may be coated on the display panel 11 in the form of liquid, and the cover glass CG may be on the adhesive layer AL. According to an embodiment, the adhesive layer AL may be on the cover glass CG in the form of a film, and the coating element 20 may be on the adhesive layer AL. According to an embodiment, the adhesive layer AL may be coated on the cover glass CG in the form of liquid, and the coating element 20 may be on the adhesive layer AL.

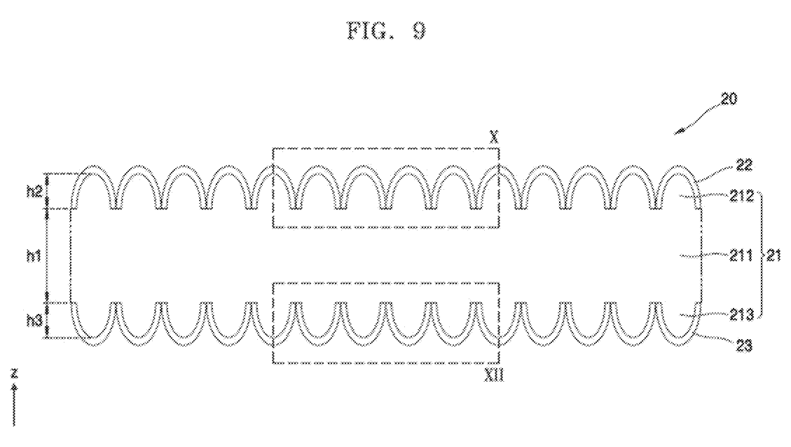

According to an embodiment, the display panel 11, the adhesive layer AL, the cover glass CG, and/or the coating element 20 may have different refractive indices. If (e.g., when) a difference between refractive indices of two adjacent layers is sufficiently large, reflection of light may occur at an interface between the two adjacent layers. According to an embodiment, external light may pass through the coating element 20 and travel to the adhesive layer AL, and reflection (e.g., of the external light) may occur due to a difference between the refractive indices of the coating element 20 and the adhesive layer AL. Light reflected by the interface between the coating element 20 and the adhesive layer AL may be visible to a user, which may cause a deterioration in the qualities of the display panel 11 and the electronic device 10. The purpose of the disclosure is to improve the quality (e.g., a display quality) of the display panel 11 and the electronic device 10 by reducing reflection of external light between the coating element 20 and the adhesive layer AL. A detailed structure of the coating element 20 that achieves the above purpose will be further described herein with reference to FIGS. 9-16.

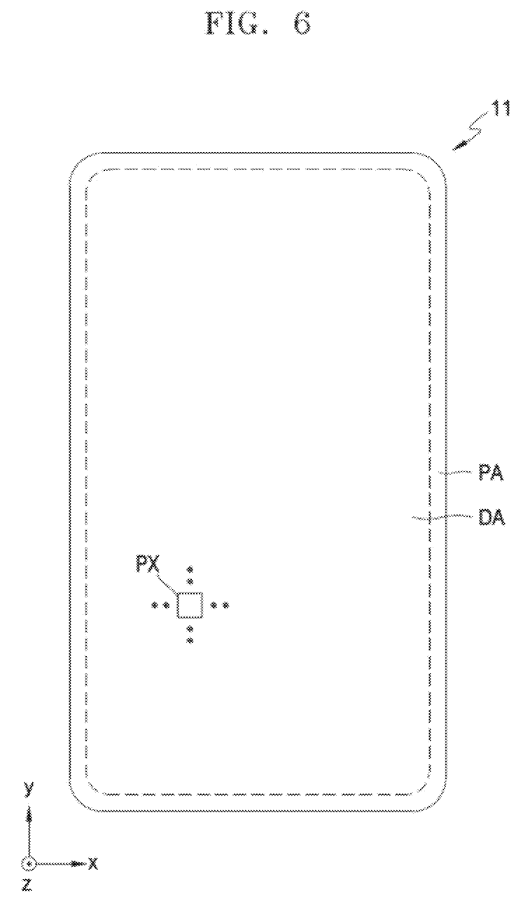

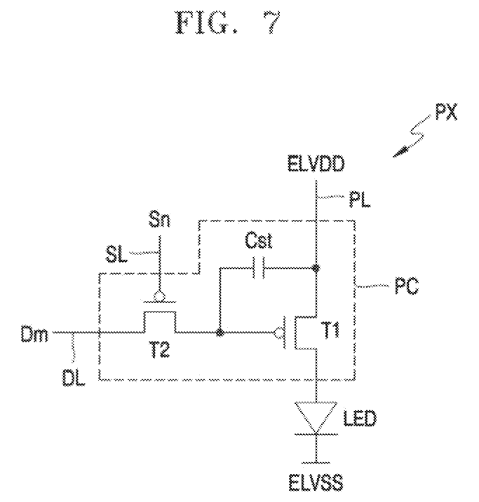

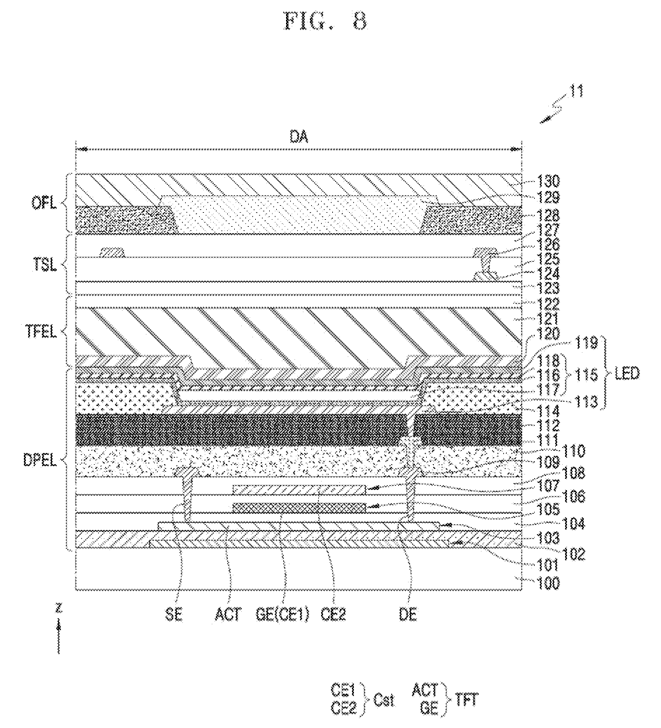

FIG. 6 is a schematic plan view of the display panel 11 according to an embodiment. FIG. 7 is an equivalent circuit diagram of a pixel of the display panel 11 according to an embodiment. FIG. 8 is a cross-sectional view of a display area DA of the display panel 11 according to an embodiment.

Referring to FIG. 6, the display panel 11 may include the display area DA, and a peripheral area PA around the display area DA. In embodiments, the display area DA, and the peripheral area PA around the display area DA may be defined in the display panel 11. In embodiments, the display panel 11 may include a substrate 100 (see FIG. 8), and the display area DA and the peripheral area PA may be defined in the substrate 100.

Pixels PX may be provided in the display area DA. Each of the pixels PX may include at least one light-emitting diode LED and a pixel circuit PC for driving the light-emitting diode LED (see FIG. 7). The light-emitting diode LED driven by the pixel circuit PC may emit light of a set or specific color (e.g., a wavelength). The display panel 11 may provide images and/or video through light emitted by a plurality of light-emitting diodes LED provided in a plurality of pixels PX. According to an embodiment, the pixel PX may include a plurality of grouped subpixels. According to an embodiment, one subpixel may include one light-emitting diode and one subpixel circuit. According to an embodiment, light-emitting diodes respectively provided in the plurality of subpixels grouped into one pixel PX may emit light of different colors (e.g., different wavelength bands). Signal lines and/or voltage lines to drive a light-emitting diode may be provided in the peripheral area PA, which is a non-display area.

FIG. 6 illustrates that the display panel 11 and the display area DA have an approximately rectangular shape having rounded corners, but the disclosure is not necessarily limited thereto. The display panel 11 and/or the display area DA may have various suitable shapes, such as a polygonal shape, a circular shape (e.g., a generally circular shape), an oval shape (e.g., a generally oval shape), and an irregular shape.

Referring to FIG. 7, the pixel circuit PC may be connected to the light-emitting diode LED and may realize light emission of pixels PX. According to an embodiment, the light-emitting diode LED may be an organic light-emitting diode. The pixel circuit PC may include a first transistor T1, a second transistor T2, and a storage capacitor Cst. According to an embodiment, the first transistor T1 may be a driving transistor, and the second transistor T2 may be a switching transistor. The second transistor T2 is connected to a scan line SL and a data line DL, and is configured to transmit, to the first transistor T1, a data signal Dm received via the data line DL according to a scan signal Sn received via the scan line SL.

The storage capacitor Cst is connected to the second transistor T2 and a driving voltage line PL, and stores a voltage corresponding to a difference between a voltage received from the second transistor T2 and a driving voltage ELVDD supplied to the driving voltage line PL.

The first transistor T1 may be connected to the driving voltage line PL and the storage capacitor Cst, and may be configured to control a driving current that flows from the driving voltage line PL to the light-emitting diode LED, in accordance with a voltage value stored in the storage capacitor Cst. The light-emitting diode LED may be connected between the first transistor T1 and a cathode voltage ELVSS. The light-emitting diode LED may emit light having a set or certain brightness due to the driving current.

The pixel circuit PC is not limited to the number of thin-film transistors, the number of capacitors, and the circuit design described above with reference to FIG. 7. The number of thin-film transistors, the number of capacitors, and the circuit design may suitably vary.

Referring to FIG. 8, the display panel 11 may include a display element layer DPEL, a thin-film encapsulation layer TFEL, a touch sensing layer TSL, and an optical functional layer OFL. The display element layer DPEL, the thin-film encapsulation layer TFEL, the touch sensing layer TSL, and the optical functional layer OFL may be sequentially on the substrate 100.

The display element layer DPEL may include a light-emitting diode LED and a thin-film transistor TFT connected to the light-emitting diode LED. According to an embodiment, FIG. 8 may schematically illustrate a portion of the pixel circuit PC described above with reference to FIG. 7. For example, the thin-film transistor TFT connected to the light-emitting diode LED may correspond to a transistor connected to the light-emitting diode LED, for example, the first transistor T1, among the transistors illustrated in FIG. 7.

The substrate 100 may include a glass material and/or polymer resin. According to an embodiment, the substrate 100 may have a stacked structure of a base layer including polymer resin and a barrier layer including an inorganic insulating material (e.g., an inorganic electrically insulating material). The polymer resin may include at least one selected from materials, such as, polyethersulfone, polyarylate, polyetherimide, polyethylene naphthalate, polyethylene terephthalate, polyphenylene sulfide, polyimide, polycarbonate, cellulose triacetate, and cellulose acetate propionate. The inorganic insulating material may include at least one selected from materials, such as silicon oxide (SiO₂) and silicon nitride (SiNₓ).

A first conductive layer 101 (e.g., a first electrically conductive layer 101) may be on the substrate 100. According to an embodiment, the first conductive layer 101 may include a power line and/or a signal line. According to an embodiment, the first conductive layer 101 may be provided under a semiconductor layer 103, for example, an active pattern ACT, to block or reduce transmission of radio waves and/or light that originate from a lower portion of the display panel 11 from being transmitted to the active pattern ACT. According to an embodiment, the first conductive layer 101 may include metal (e.g., having light-blocking properties). According to an embodiment, the first conductive layer 101 may include at least one selected from materials, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may have a single layer or multi-layer structure.

A first insulating layer 102 (e.g., a first electrically insulating layer 102) may be on the first conductive layer 101. The first insulating layer 102 may entirely cover the first conductive layer 101. The first insulating layer 102 may have a flat upper surface. The first insulating layer 102 may include an inorganic insulating material (e.g., an inorganic electrically insulating material). According to an embodiment, the first insulating layer 102 may include at least one selected from materials, such as, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layer or multi-layer structure. According to an embodiment, the first insulating layer 102 may be a buffer layer.

The thin-film transistor TFT may be on the first insulating layer 102. The thin-film transistor TFT may include the active pattern ACT and a gate electrode GE.

The semiconductor layer 103 may be on the first insulating layer 102. The semiconductor layer 103 may include the active pattern ACT. The active pattern ACT may include a source region that overlaps a source electrode SE, a drain region that overlaps a drain electrode DE, and a channel region between the source region and the drain region. The channel region may overlap the gate electrode GE. The source region and the drain region may be regions doped with impurities (e.g., a dopant).

A second insulating layer 104 (e.g., a second electrically insulating layer 104) may be on the semiconductor layer 103. The second insulating layer 104 may cover the semiconductor layer 103, for example, the active pattern ACT. The second insulating layer 104 may include an inorganic insulating material (e.g., an inorganic electrically insulating material). According to an embodiment, the second insulating layer 104 may include at least one selected from materials, such as, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layer or multi-layer structure. According to an embodiment, the second insulating layer 104 may be a first gate insulating layer (e.g., a first gate electrically insulating layer).

A storage capacitor Cst may be on the second insulating layer 104. The storage capacitor Cst may include a first capacitor electrode CE1 and a second capacitor electrode CE2. The first capacitor electrode CE1 and the second capacitor electrode CE2 may overlap each other, and the second capacitor electrode CE2 may be on the first capacitor electrode CE1.

A second conductive layer 105 (e.g., a second electrically conductive layer 105) may be on the second insulating layer 104. The second conductive layer 105 may include the gate electrode GE of the thin-film transistor TFT, and the first capacitor electrode CE1 of the storage capacitor Cst. According to an embodiment, the gate electrode GE and the first capacitor electrode CE1 may be provided integrally as illustrated in FIG. 8. According to an embodiment, the gate electrode GE and the first capacitor electrode CE1 may be provided individually. According to an embodiment, the second conductive layer 105 may include at least one selected from materials, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may have a single layer or multi-layer structure.

A third insulating layer 106 (e.g., a third electrically insulating layer 106) may be on the second conductive layer 105. The third insulating layer 106 may include the second conductive layer 105, for example, the gate electrode GE and the first capacitor electrode CE1. The third insulating layer 106 may include an inorganic insulating material (e.g., an inorganic electrically insulating material). According to an embodiment, the third insulating layer 106 may include at least one selected from materials, such as, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layer or multi-layer structure. According to an embodiment, the third insulating layer 106 may be a second gate insulating layer (e.g., a second gate electrically insulating layer).

A third conductive layer 107 (e.g., a third electrically conductive layer 107) may be on the third insulating layer 106. The third conductive layer 107 may include the second capacitor electrode CE2. The second capacitor electrode CE2 may overlap the first capacitor electrode CE1. According to an embodiment, the third conductive layer 107 may include at least one selected from materials, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may have a single layer or multi-layer structure.

A fourth insulating layer 108 (e.g., a fourth electrically insulating layer 108) may be on the third conductive layer 107. The fourth insulating layer 108 may cover the third conductive layer 107, for example, the second capacitor electrode CE2. The fourth insulating layer 108 may include an inorganic insulating material (e.g., an inorganic electrically insulating material). According to an embodiment, the fourth insulating layer 108 may include at least one selected from materials, such as, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layer or multi-layer structure. According to an embodiment, the fourth insulating layer 108 may be an interlayer insulating layer (e.g., an interlayer electrically insulating layer).

A fourth conductive layer 109 (e.g., a fourth electrically conductive layer 109) may be on the fourth insulating layer 108. The fourth conductive layer 109 may include the source electrode SE and the drain electrode DE. The source electrode SE may overlap the source region of the active pattern ACT. The source electrode SE may be connected to the active pattern ACT (e.g., to the source region) through an opening defined in the second, third, and fourth insulating layers 104, 106, and 108. The drain electrode DE may overlap the drain region of the active pattern ACT. The drain electrode DE may be connected to the active pattern ACT (e.g., to the drain region) through an opening defined in the second, third, and fourth insulating layers 104, 106, and 108. According to an embodiment, the fourth conductive layer 109 may include at least one selected from materials, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may have a single layer or multi-layer structure.

FIG. 8 illustrates an embodiment in which each of the second, third, and fourth insulating layers 104, 106, and 108 has a flat upper surface, but the disclosure is not necessarily limited thereto. The second, third, and fourth insulating layers 104, 106, and 108 may have upper surface shapes (e.g., irregularities) corresponding to the shapes of layers respectively provided below the second, third, and fourth insulating layers 104, 106, and 108.

A fifth insulating layer 110 (e.g., a fifth electrically insulating layer 110) may be on the fourth conductive layer 109. The fifth insulating layer 110 may cover the fourth conductive layer 109, for example, the source electrode SE and the drain electrode DE. The fifth insulating layer 110 may have a flat upper surface. The fifth insulating layer 110 may include an organic insulating material (e.g., an organic electrically insulating material). According to an embodiment, the fifth insulating layer 110 may include at least one selected from materials, such as, a commercial polymer (such as, benzocyclobutene (BCB), polyimide, hexamethyldisiloxane (HMDSO), polymethyl methacrylate (PMMA) and/or polystyrene (PS)), a polymer derivative having a phenol-based group, an acryl-based polymer, an imide-based polymer, an aryl ether-based polymer, an amide-based polymer, a fluorine-based polymer, a p-xylene-based polymer, and/or a vinyl alcohol-based polymer, and may have a single layer or multi-layer structure. According to an embodiment, the fifth insulating layer 110 may be a first via layer.

A fifth conductive layer 111 (e.g., a fifth electrically conductive layer 111) may be on the fifth insulating layer 110. The fifth conductive layer 111 may include a contact metal that connects the fourth conductive layer 109, for example, the drain electrode DE, to a first electrode 113 of the light-emitting diode LED. In embodiments, the fifth conductive layer 111 may also include gate electrodes, signal lines, power lines, and/or the like of other transistors. According to an embodiment, the fifth conductive layer 111 may include at least one selected from materials, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may have a single layer or multi-layer structure.

A sixth insulating layer 112 (e.g., a sixth electrically insulating layer 112) may be on the fifth conductive layer 111. The sixth insulating layer 112 may cover the fifth conductive layer 111. The sixth insulating layer 112 may have a flat upper surface. The sixth insulating layer 112 may include an organic insulating material (e.g., an organic electrically insulating material). According to an embodiment, the sixth insulating layer 112 may include at least one selected from materials, such as, a commercial polymer (such as, benzocyclobutene (BCB), polyimide, hexamethyldisiloxane (HMDSO), polymethyl methacrylate (PMMA) and/or polystyrene (PS)), a polymer derivative having a phenol-based group, an acryl-based polymer, an imide-based polymer, an aryl ether-based polymer, an amide-based polymer, a fluorine-based polymer, a p-xylene-based polymer, and/or a vinyl alcohol-based polymer, and may have a single layer or multi-layer structure. According to an embodiment, the sixth insulating layer 112 may be a second via layer.

A light-emitting diode LED may be on the sixth insulating layer 112. The light-emitting diode LED may include a first electrode 113 and a second electrode 119 opposite to each other, and an intermediate layer 115 between the first electrode 113 and the second electrode 119. According to an embodiment, the first electrode 113 of the light-emitting diode LED may correspond to an anode, and the second electrode 119 thereof may correspond to a cathode.

The first electrode 113 of the light-emitting diode LED may be on the sixth insulating layer 112. The first electrode 113 may be connected to the fifth conductive layer 111 through an opening defined in the sixth insulating layer 112. The first electrode 113 may be (e.g., electrically) connected to the thin-film transistor TFT via the fifth conductive layer 111 and the drain electrode DE. The first electrode 113 may include a conductive oxide (e.g., an electrically conductive oxide), such as indium tin oxide (ITO), indium zinc oxide (IZO), zinc oxide (ZnO), indium oxide (In₂O₃), indium gallium oxide (IGO), and/or aluminum zinc oxide (AZO). The first electrode 113 may include a reflective layer including silver (Ag), magnesium (Mg), aluminum (Al), platinum (Pt), palladium (Pd), gold (Au), nickel (Ni), neodymium (Nd), iridium (Ir), chromium (Cr), and/or a compound of these materials. The configuration and material of the first electrode 113 are not limited to those described above, and various suitable modifications may be made to the configuration and material of the first electrode 113.

A pixel defining layer 114 may be on the sixth insulating layer 112. The pixel defining layer 114 may cover an edge of the first electrode 113. In embodiments, the pixel defining layer 114 may have an opening to expose a portion of a center of the first electrode 113. A size and shape of an emission region of the light-emitting diode LED may be determined by the opening of the pixel defining layer 114. According to an embodiment, the pixel defining layer 114 may include an organic insulating material (e.g., an organic electrically insulating material). According to an embodiment, the pixel defining layer 114 may include at least one selected from materials, such as, a commercial polymer (such as, benzocyclobutene (BCB), polyimide, hexamethyldisiloxane (HMDSO), polymethyl methacrylate (PMMA) and/or polystyrene (PS)), a polymer derivative having a phenol-based group, an acryl-based polymer, an imide-based polymer, an aryl ether-based polymer, an amide-based polymer, a fluorine-based polymer, a p-xylene-based polymer, and/or a vinyl alcohol-based polymer, and may have a single layer or multi-layer structure.

The intermediate layer 115 may be on the first electrode 113. The intermediate layer 115 may include first and second common layers 116 and 118 on the pixel defining layer 114, and an emission layer 117 provided within the opening of the pixel defining layer 114. The first common layer 116 may be on the second common layer 118. According to an embodiment, the first common layer 116 may be on the pixel defining layer 114, the emission layer 117 may be on the first common layer 116 within the opening of the pixel defining layer 114, and the second common layer 118 may be on the first common layer 116 to cover the emission layer 117. In embodiments, the emission layer 117 may be provided within the opening of the pixel defining layer 114 and may be between the first common layer 116 and the second common layer 118.

The emission layer 117 may include a high molecular weight material or a low molecular weight material that emits light of a set or certain color if (e.g., when) a current (e.g., an electric current) flows. The first common layer 116 may include an electron transport layer (ETL) and/or an electron injection layer (EIL). The second common layer 118 may include a hole transport layer (HTL) and/or a hole injection layer (HIL). According to some embodiments, the first common layer 116 or the second common layer 118 may be omitted. According to some embodiments, the locations of the first common layer 116 and the second common layer 118 may be interchanged.

The second electrode 119 may be on the intermediate layer 115. For example, the second electrode 119 may be on the second common layer 118. The second electrode 119 may entirely cover the intermediate layer 115. The second electrode 119 may include a conductive material (e.g., an electrically conductive material). For example, the second electrode 119 may include a transparent layer (or a semi-transparent layer) including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) and/or an alloy of these materials. In embodiments, the second electrode 119 may further include a layer including an oxide, such as indium tin oxide (ITO), indium zinc oxide (IZO), zinc oxide (ZnO), and/or indium oxide (In₂O₃), on a transparent layer (or a semi-transparent layer) including any of the aforementioned materials.

A thin-film encapsulation layer TFEL may be on the second electrode 119 and may entirely cover the light-emitting diode LED. The thin-film encapsulation layer TFEL may include at least one inorganic layer and at least one organic layer. According to an embodiment, the thin-film encapsulation layer TFEL may include a first inorganic encapsulation layer 120, a second inorganic encapsulation layer 122, and an organic encapsulation layer 121 between the first inorganic encapsulation layer 120 and the second inorganic encapsulation layer 122. According to an embodiment, the first inorganic encapsulation layer 120 and the second inorganic encapsulation layer 122 may have upper surfaces of shapes (e.g., irregularities) according to the shapes of layers provided below the first inorganic encapsulation layer 120 and the second inorganic encapsulation layer 122. According to an embodiment, the organic encapsulation layer 121 may have a flat upper surface.

The first inorganic encapsulation layer 120 and/or the second inorganic encapsulation layer 122 may include at least one selected from materials, such as, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layer or multi-layer structure. The organic encapsulation layer 121 may include a polymer-based material. Examples of the polymer-based material may include a silicon-based resin, an acryl-based resin, an epoxy-based resin, polyimide, and/or polyethylene.

The touch sensing layer TSL may be on the thin-film encapsulation layer TFEL. The touch sensing layer TSL may include a touch electrode layer to detect an external input, such as a touch event, and a touch insulating layer (e.g., a touch electrically insulating layer) between electrode layers. The touch sensing layer TSL may include a first touch insulating layer 123 (e.g., a first touch electrically insulating layer 123), a first touch electrode layer 124, a second touch insulating layer 125 (e.g., a second touch electrically insulating layer 125), a second touch electrode layer 126, and a third touch insulating layer 127 (e.g., a third touch electrically insulating layer 127).

The first touch insulating layer 123 may be on the thin-film encapsulation layer TFEL, for example, on the second inorganic encapsulation layer 122 of the thin-film encapsulation layer TFEL. The first touch electrode layer 124 may be on the first touch insulating layer 123. The second touch insulating layer 125 may be on the first touch electrode layer 124 and may cover the first touch electrode layer 124 (e.g., a first touch conductive layer 124). The second touch electrode layer 126 may be on the second touch insulating layer 125. The third touch insulating layer 127 may be on the second touch electrode layer 126 and may cover the second touch electrode layer 126. The second touch electrode layer 126 may be connected to the first touch electrode layer 124 through an opening defined in the second touch insulating layer 125. According to an embodiment, the second touch electrode layer 126 may include a sensing electrode, and the first touch electrode layer 124 may include a bridge electrode.

According to an embodiment, the first touch insulating layer 123 may include an inorganic insulating material (e.g., an inorganic electrically insulating material). According to an embodiment, the first touch insulating layer 123 may include at least one selected from materials, such as, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single-layer or multi-layer structure.

According to an embodiment, the second touch insulating layer 125 and the third touch insulating layer 127 may include organic insulating materials (e.g., organic electrically insulating materials). According to an embodiment, the second touch insulating layer 125 and/or the third touch insulating layer 127 may include acryl-based organic insulating materials (e.g., acryl-based organic electrically insulating materials). According to an embodiment, the second touch insulating layer 125 and/or the third touch insulating layer 127 may have flat upper surfaces.

The first touch electrode layer 124 and the second touch electrode layer 126 may not overlap the entire emission region of the light-emitting diode LED. According to an embodiment, the first touch electrode layer 124 and the second touch electrode layer 126 may not overlap the emission layer 117 of the light-emitting diode LED. In embodiments, the first touch electrode layer 124 and the second touch electrode layer 126 may have openings that overlap the emission region or the emission layer 117 of the light-emitting diode LED.

The optical functional layer OFL may be on the touch sensing layer TSL. The optical functional layer OFL may include a light-blocking layer 128, a color filter layer 129, and an overcoat layer 130. The overcoat layer 130 may cover the light-blocking layer 128 and the color filter layer 129, and may have a flat upper surface.

The light-blocking layer 128 may be on the touch sensing layer TSL, for example, the third touch insulating layer 127. The light-blocking layer 128 may include a light-blocking material, and may cover the first and second touch electrode layers 124 and 126 to prevent or reduce reflectance of external light from the first and second touch electrode layers 124 and 126 and being visible to a user. In embodiments, the light-blocking layer 128 is not limited to this effect, and may provide various other suitable effects. The light-blocking layer 128 may have an opening to allow light emitted by the light-emitting diode LED to pass therethrough. The opening of the light-blocking layer 128 may overlap the light-emitting diode LED, for example, the emission layer 117.

The color filter layer 129 may be on the light-blocking layer 128. The color filter layer 129 may overlap the opening of the light-blocking layer 128, and a portion of the color filter layer 129 may be provided within the opening of the light-blocking layer 128. The color filter 129 may transmit light of a color (or a wavelength band) corresponding to light emitted by the emission layer 117 of the light-emitting diode LED. For example, if (e.g., when) the emission layer 117 of the light-emitting diode LED emits red light, the color filter layer 129 may be provided to transmit light in a red wavelength band.

FIG. 9 is a cross-sectional view of the coating element 20 according to an embodiment.

Referring to FIG. 9, the coating element 20 may include a cover film 21, a first coating 22, and a second coating 23. The cover film 21 may include a main body 211, a first protrusion pattern 212, and a second protrusion pattern 213. The main body 211, the first protrusion pattern 212, and the second protrusion pattern 213 of the cover film 21 may be integrally formed.

The first protrusion pattern 212 may be formed on a first surface (e.g., an upper surface) of the cover film 21. Referring to FIG. 5 together, the first surface of the cover film 21 may be a surface that is directed in a direction away from the display panel 11 or the adhesive layer AL. According to an embodiment, the first protrusion pattern 212 may protrude from the main body 211 in the direction away from the display panel 11 or the adhesive layer AL. According to an embodiment, the first surface of the cover film 21 may be a surface that is directed in a z-axis direction. According to an embodiment, the first protrusion pattern 212 may protrude from the main body 211 in the z-axis direction. According to an embodiment, the first protrusion pattern 212 may be provided in the shape of a plurality of parabolas. According to an embodiment, the plurality of parabolas of the first protrusion pattern 212 may have the same shape and/or dimensions (e.g., as each other).

The second protrusion pattern 213 may be on a second surface (e.g., a lower surface) of the cover film 21. According to an embodiment, the second surface may be a surface opposite to the first surface. Referring to FIG. 5 together, the second surface of the cover film 21 may be a surface that faces or is adjacent to the display panel 11 or the adhesive layer AL. According to an embodiment, the second protrusion pattern 213 may protrude from the main body 211 in a direction toward the display panel 11 or the adhesive layer AL. According to an embodiment, the second surface of the cover film 21 may be a surface that is directed in a direction opposite to the z-axis direction. According to an embodiment, the second protrusion pattern 213 may protrude from the main body 211 in the direction opposite to the z-axis direction. According to an embodiment, the second protrusion pattern 213 may be provided in the shape of a plurality of parabolas. According to an embodiment, the plurality of parabolas of the second protrusion pattern 213 may have the same shape and/or dimensions (e.g., as each other). According to an embodiment, the first protrusion pattern 212 and the second protrusion pattern 213 may have the same shapes (e.g., as each other). According to an embodiment, the first protrusion pattern 212 and the second protrusion pattern 213 may have different configurations, shapes, and/or dimensions.

In this specification, considering an embodiment in which the display panel 11 and the adhesive layer AL are provided under the coating element 20, a surface of the cover film 21 that faces the adhesive layer AL is expressed as a lower surface, and an opposite surface is expressed as an upper surface. In embodiments, the disclosure is not necessarily limited to these "upper" and "lower" expressions, and these expressions may change according to the arrangement of the display panel 11, the adhesive layer AL, and the coating element 20.

According to an embodiment, the first protrusion pattern 212 may prevent (or at least reduce) interfacial reflection (e.g., on the first surface of the cover film 21) due to a difference between refractive indices of the air and the cover film 21. According to an embodiment, the second protrusion pattern 213 may prevent (or at least reduce) interfacial reflection (e.g., on the second surface of the cover film 21) due to a difference between refractive indices of the adhesive layer AL (see FIG. 5) and the cover film 21.

A thickness (or a height) of the main body 211 of the cover film 21 may be defined as a first height h1. A thickness (or a height) of the first protrusion pattern 212 of the cover film 21, for example, a height of each parabola of the first protrusion pattern 212, may be defined as a second height h2. A thickness (or a height) of the second protrusion pattern 213 of the cover film 21, for example, a height of each parabola of the second protrusion pattern 213, may be defined as a third height h3.

According to an embodiment, the first height h1 may be about 50 micrometers (μm) to about 200 micrometers (μm). According to an embodiment, the second height h2 may be about 200 nanometers (nm) to about 400 nanometers (nm). According to an embodiment, the third height h3 may be about 200 nanometers (nm) to ab 400 nanometers (nm). According to an embodiment, the second height h2 and the third height h3 may be equal to each other. According to an embodiment, an overall thickness of the cover film 21, for example, a sum of the first height h1, the second height h2, and the third height h3, may be about 50 micrometers (μm) to about 200 micrometers (μm).

According to an embodiment, the cover film 21 may include a polymer. According to an embodiment, the cover film 21 may include at least one of the material selected from the group consisting of polymers, such as polycarbonate (PC), polymethyl methacrylate (PMMA), polyethylene terephthalate (PET), and polyimide (PI). In embodiments, the disclosure is not limited to the cover film 21 including a specific material.

The first coating 22 may be on the first surface of the cover film 21. According to an embodiment, the first coating 22 may be on the first protrusion pattern 212. According to an embodiment, the first coating 22 may entirely cover the first protrusion pattern 212. According to an embodiment, the first coating 22 may be connected in a region between two adjacent parabolas of the first protrusion pattern 212, and may cover an upper surface of the cover film 21, for example, an upper surface of the main body 211, corresponding to the region. According to an embodiment, the first coating 22 may be provided as a single body on the first protrusion pattern 212. According to an embodiment, the first coating 22 may be provided as a single body according to a shape of the first protrusion pattern 212. According to an embodiment, the first coating 22 may be provided according to irregularities of the first protrusion pattern 212. Accordingly, even if (e.g., when) the first protrusion pattern 212 is covered by the first coating 22, the shape (e.g., irregularities) of the first protrusion pattern 212 may be at least partially visible.

According to an embodiment, the first coating 22 may protect the cover film 21, for example, the first protrusion pattern 212, from external impact. According to an embodiment, the first coating 22 may include an inorganic insulating material (e.g., an inorganic electrically insulating material). According to an embodiment, the first coating 22 may include aluminum oxide (Al₂O₃). In embodiments, the disclosure is not limited to a specific material, and the first coating 22 may include any suitable material having suitable or sufficient hardness to protect the first protrusion pattern 212.

The second coating 23 may be on the second surface of the cover film 21. According to an embodiment, the second coating 23 may be on the second protrusion pattern 213. According to an embodiment, the second coating 23 may entirely cover the second protrusion pattern 213. According to an embodiment, the second coating 23 may be connected in a region between two adjacent parabolas of the second protrusion pattern 213, and may cover a lower surface of the cover film 21, for example, a lower surface of the main body 211, corresponding to the region. According to an embodiment, the second coating 23 may be provided as a single body on the second protrusion pattern 213. According to an embodiment, the second coating 23 may be provided according to a shape of the second protrusion pattern 213. According to an embodiment, the second coating 23 may be provided according to irregularities of the second protrusion pattern 213. Accordingly, even if (e.g., when) the second protrusion pattern 213 is covered by the second coating 23, the shape (e.g., irregularities) of the second protrusion pattern 213 may be at least partially visible.

Referring to FIG. 5 together, according to an embodiment, the second coating 23 may supplement the difference between the refractive indices of the cover film 21 and the adhesive layer AL. According to an embodiment, a refractive index of the second coating 23 may be between the refractive index of the cover film 21 and the refractive index of the adhesive layer AL. In embodiments, the second coating 23 may have a refractive index between the refractive index of the cover film 21 and the refractive index of the adhesive layer AL. If (e.g., when) the second coating 23 is not present, a refractive index gradient (profile) between the cover film 21 and the adhesive layer AL may include an abrupt step-by-step change due to the difference between the refractive indices of the cover film 21 and the adhesive layer AL, which may cause interface reflection at a boundary between the second protrusion pattern 213 and the adhesive layer AL. In embodiments, the interface reflection may be somewhat reduced due to the presence of the second protrusion pattern 213. In embodiments, if (e.g., when) the second coating 23 is provided, the gradient of refractive index along the cover film 21, the second coating 23, and the adhesive layer AL may be made gentle, and thus the interface reflection may be further reduced.

According to an embodiment, the second coating 23 may include an inorganic insulating material (e.g., an inorganic electrically insulating material). According to an embodiment, the second coating 23 may include silicon oxide (SiO₂). In embodiments, the disclosure is not limited to a specific material, and the second coating 23 may include any suitable material having a refractive index between a refractive index of the second protrusion pattern 213 and the refractive index of the adhesive layer AL.

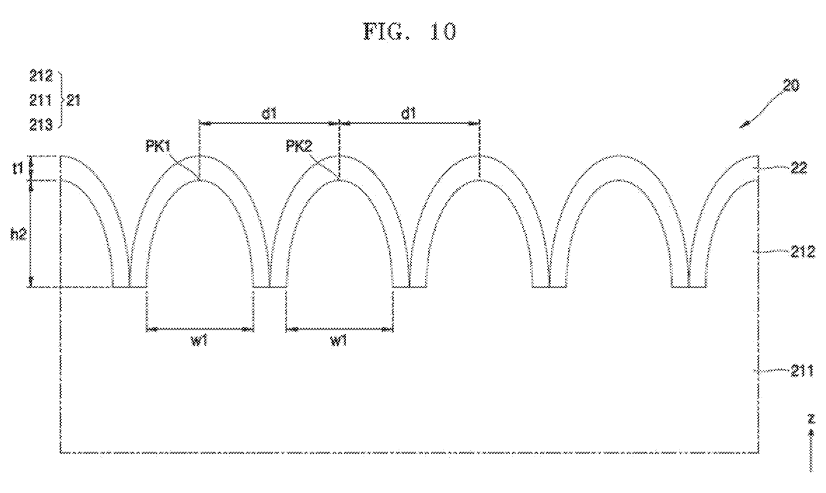

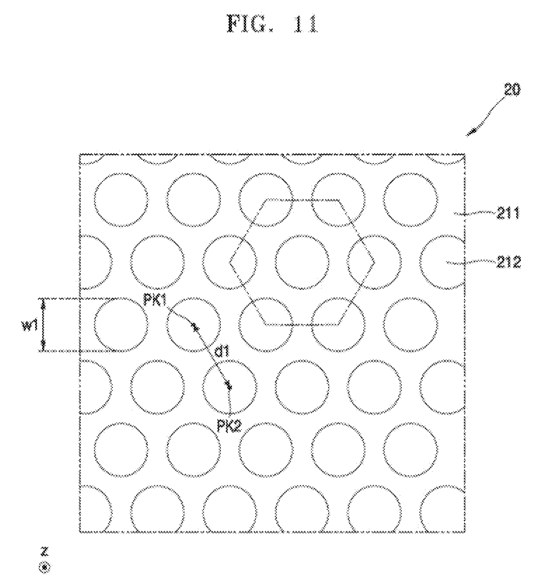

FIG. 10 is a magnified cross-sectional view of the cover film 21 according to an embodiment. FIG. 11 is a plan view of the cover film 21 according to an embodiment. FIG. 10 may be a magnified cross-sectional view of a region X of FIG. 9.

Referring to FIGS. 10 and 11, the first protrusion pattern 212 on the first surface of the cover film 21 may include a plurality of parabolas.

According to an embodiment, in a plan view, the first protrusion pattern 212 may have a circular shape (e.g., a generally circular shape) as illustrated in FIG. 11. According to an embodiment, the plurality of parabolas (or circles) of the first protrusion pattern 212 may be provided along a virtual hexagon (e.g., a regular hexagon). The hexagon is depicted in a one dot-dashed line of FIG. 11. According to an embodiment, a center of each circle may be on each corner of a regular hexagon. The foregoing is an example, and the disclosure is not necessarily limited to the above-described planar shape of the first protrusion pattern 212 or the above-described arrangement of first protrusion pattern(s) 212. According to an embodiment, the first protrusion pattern 212 may be provided in a planar shape of a hexagon, and each corner of the hexagon may be angled or rounded. According to an embodiment, the first protrusion patterns 212 may be provided along any polygon other than a hexagon, for example, along a triangle or a quadrangle.

The first protrusion pattern 212 may have the above-described second height h2 and may have a first width w1. According to an embodiment, one of the plurality of parabolas of the first protrusion pattern 212 may have a first peak PK1. According to an embodiment, a vertical height from a lowermost portion of a parabola, for example, an upper surface of the main body 211 of the cover film 21, to the first peak PK1, for example, a height in the z-axis direction, may be defined as a second height h2. According to an embodiment, a width of the lowest portion of a parabola, for example, a width of the parabola on the same level as the upper surface of the main body 211 of the cover film 21, may be defined as a first width w1. According to an embodiment, referring to FIG. 11, a diameter of the circle of the first protrusion pattern 212 may be defined as the first width w1.

According to an embodiment, a parabola adjacent to a parabola having the first peak PK1 may have a second peak PK2. According to an embodiment, a horizontal distance between the first peak PK1 and the second peak PK2, for example, a distance measured along a direction perpendicular (e.g., substantially perpendicular) to the z-axis direction, may be defined as a first distance d1. According to an embodiment, the first distance d1 may be understood as a 'period' in which the parabolas of the first protrusion pattern 212 are repeated.

According to an embodiment, the first distance d1 (or the period of the first protrusion pattern 212) may be about 250 nanometers (nm) to about 300 nanometers (nm). According to an embodiment, the first width w1 may be less than the first distance d1. Accordingly, the parabolas of the first protrusion pattern 212 may be spaced apart from each other (e.g., by a difference between the first distance d1 and the first width w1). According to an embodiment, a ratio between the first width w1 and the first distance d1, that is, a value obtained by dividing the first width w1 by the first distance d1, may be defined as a 'filling rate' of the first protrusion pattern 212. According to an embodiment, the filling rate of the first protrusion pattern 212 may be about 40% to about 100%. According to an embodiment, the filling rate of the first protrusion pattern 212 may be about 70% to about 100%. According to an embodiment, if (e.g., when) the filling rate of the first protrusion pattern 212 is 100%, adjacent parabolas (or circles) of the first protrusion pattern 212 may contact each other.

A thickness of the first coating 22 may be defined as a first thickness t1. According to an embodiment, the first coating 22 may have a substantially constant thickness regardless of locations on the first protrusion pattern 212. According to an embodiment, the first coating 22 may have different thicknesses according to locations on the first protrusion pattern 212. In embodiments, the first thickness t1 of the first coating 22 may refer to an average thickness of the first coating 22, or may refer to a thickness of the first coating 22 on an arbitrary location or any suitable location of the first coating 22. According to an embodiment, the first thickness t1 may be about 30 nanometers (nm) to about 50 nanometers (nm).

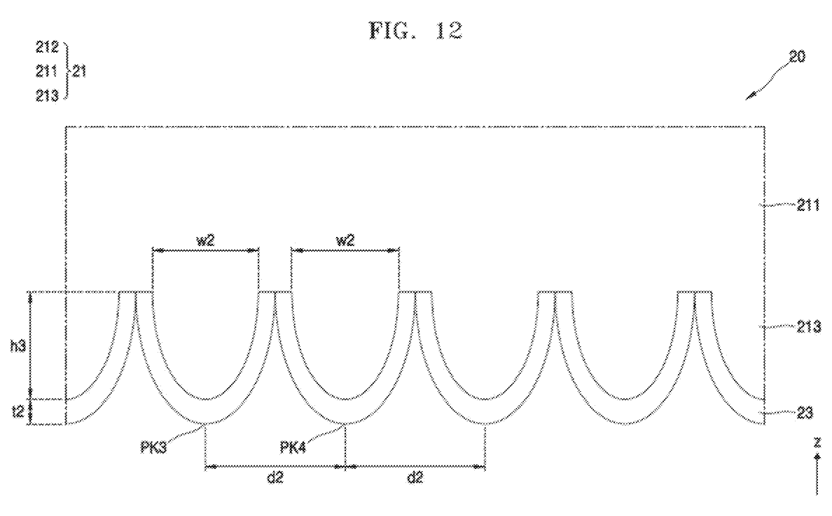

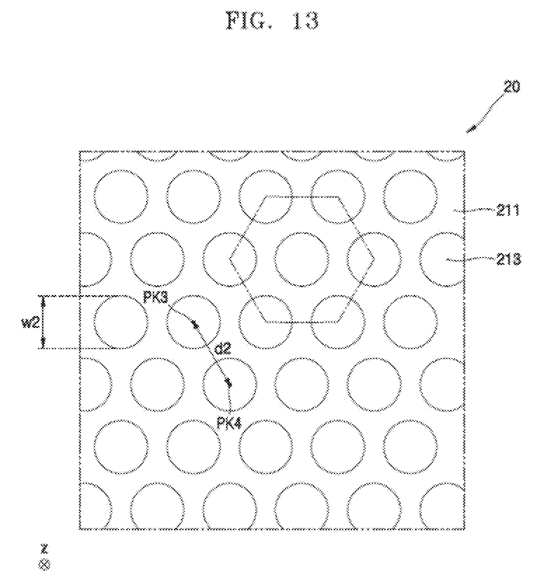

FIG. 12 is a magnified cross-sectional view of the cover film 21 according to an embodiment. FIG. 13 is a bottom view of the cover film 21 according to an embodiment. FIG. 12 may be a magnified cross-sectional view of a region XII of FIG. 9.

Referring to FIGS. 12 and 13, similar to the embodiment of the first protrusion pattern 212, the second protrusion pattern 213 on the second surface of the cover film 21 may include a plurality of parabolas.

According to an embodiment, in a plan view, the second protrusion pattern 213 may have a circular shape (e.g., a generally circular shape) as illustrated in FIG. 13. According to an embodiment, the plurality of parabolas (or circles) of the second protrusion pattern 213 may be provided along a virtual hexagon (e.g., a regular hexagon). The hexagon is depicted in a one-dot-dashed line of FIG. 13. According to an embodiment, a center of each circle may be on each corner of a regular hexagon. The foregoing is an example, and the disclosure is not necessarily limited to the above-described planar shape of the second protrusion pattern 213 or the above-described arrangement of second protrusion pattern(s) 213. According to an embodiment, the second protrusion pattern 213 may be provided in a planar shape of a hexagon, and each corner of the hexagon may be angled or rounded. According to an embodiment, the second protrusion patterns 213 may be provided along any suitable polygon other than a hexagon, for example, along a triangle or a quadrangle.

The second protrusion pattern 213 may have the above-described third height h3 and may have a second width w2. According to an embodiment, one of the plurality of parabolas of the second protrusion pattern 213 may have a third peak PK3. According to an embodiment, a vertical height from an uppermost portion of a parabola, for example, a lower surface of the main body 211 of the cover film 21, to the third peak PK3, for example, a height in the z-axis direction, may be defined as a third height h3. According to an embodiment, a width of the uppermost portion of a parabola, for example, a width of the parabola on the same level as the lower surface of the main body 211 of the cover film 21, may be defined as a second width w2. According to an embodiment, referring to FIG. 13, a diameter of the circle of the second protrusion pattern 213 may be defined as the second width w2.

According to an embodiment, a parabola adjacent to a parabola having the third peak PK3 may have a fourth peak PK4. According to an embodiment, a horizontal distance between the third peak PK3 and the fourth peak PK4, for example, a distance measured along a direction perpendicular (e.g., substantially perpendicular) to the z-axis direction, may be defined as a second distance d2. According to an embodiment, the second distance d2 may be understood as a 'period' in which the parabolas of the second protrusion pattern 213 are repeated.

According to an embodiment, the second distance d2 (or the period of the second protrusion pattern 213) may be about 250 nanometers (nm) to about 300 nanometers (nm). According to an embodiment, the first distance d1 (or the period of the first protrusion pattern 212) of FIG. 10 and the second distance d2 (or the period of the second protrusion pattern 213) may be equal to each other. According to an embodiment, the second width w2 may be less than the second distance d2. Accordingly, the parabolas of the second protrusion pattern 213 may be spaced apart from each other (e.g., by a difference between the second distance d2 and the second width w2). According to an embodiment, a ratio between the second width w2 and the second distance d2, for example, a value obtained by dividing the second width w2 by the second distance d2, may be defined as a filling rate of the second protrusion pattern 213. According to an embodiment, the filling rate of the second protrusion pattern 213 may be about 40% to about 100%. According to an embodiment, the filling rate of the second protrusion pattern 213 may be about 70% to about 100%. According to an embodiment, if (e.g., when) the filling rate of the second protrusion pattern 213 is 100%, adjacent parabolas (or circles) of the second protrusion pattern 213 may contact each other. According to an embodiment, the filling rate of the first protrusion pattern 212 of FIG. 10 and the filling rate of the second protrusion pattern 213 may be equal to each other.

A thickness of the second coating 23 may be defined as a second thickness t2. According to an embodiment, the second coating 23 may have a substantially constant thickness regardless of locations on the second protrusion pattern 213. According to an embodiment, the second coating 23 may have different thicknesses according to locations on the second protrusion pattern 213. In embodiments, the second thickness t2 of the second coating 23 may refer to an average thickness of the second coating 23, or may refer to a thickness of the second coating 23 on an arbitrary location or any suitable location of the second coating 23. According to an embodiment, the second thickness t2 may be about 10 nanometers (nm) to about 100 nanometers (nm). According to an embodiment, the second thickness t2 may be about 20 nanometers (nm) to about 50 nanometers (nm).

According to an embodiment, the second thickness t2 may suitably vary according to the third height h3. According to an embodiment, the second thickness t2 may be proportional to the third height h3. According to an embodiment, the third height h3 may be about 200 nanometers (nm), and the second thickness t2 may be about 15 nanometers (nm). According to an embodiment, the third height h3 may be about 300 nanometers (nm), and the second thickness t2 may be about 25 nanometers (nm).

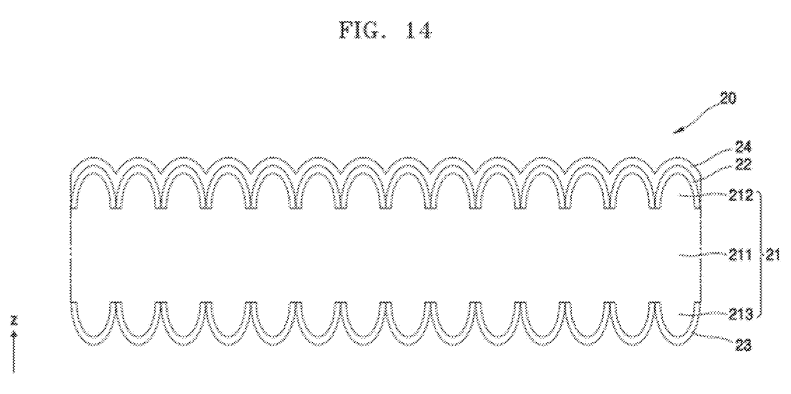

FIG. 14 is a cross-sectional view of the coating element 20 according to an embodiment.

Referring to FIG. 14, the coating element 20 may include a cover film 21, a first coating 22, a second coating 23, and a third coating 24. The third coating 24 may be on the first coating 22.

According to an embodiment, the third coating 24 may include a different material from a material included in the first coating 22 and/or the second coating 23. According to an embodiment, the third coating 24 may come into contact with a part of a user's body and/or a device (e.g., a stylus pen) for a touch input, for example. According to an embodiment, the third coating 24 may serve to supplement the hardness of the coating element 20. According to an embodiment, the third coating 24 may serve to reduce a frictional force on the upper surface of the coating element 20. In embodiments, the third coating 24 may facilitate smooth sliding on the upper surface of the coating element 20.

According to an embodiment, the third coating 24 may be provided in a shape corresponding to irregularities of the first coating 22 formed by the first protrusion pattern 212. In embodiments, the third coating 24 may also have irregularities corresponding to the irregularities of the first protrusion pattern 212. According to an embodiment, unlike what shown in FIG. 14, the third coating 24 may be provided as a planarization layer.

According to an embodiment, the third coating 24 may include a silicon-based material, such as polydimethylsiloxane (PDMS), phenylmethylsilicon, silicon oxide (SiO₂), and/or hexamethyldisiloxane (HMDSO). According to an embodiment, the third coating 24 may include a fluorine-based material, such as polytetrafluoroethylene (PTFE), fluorinated ethylene propylene (FEP), and/or perfluoropolyether (PFPE). In embodiments, the disclosure is not limited to the third coating 24 of a specific material, and the third coating 24 may include any other suitable material having a suitable or required level of hardness and a suitable or required level of frictional force.

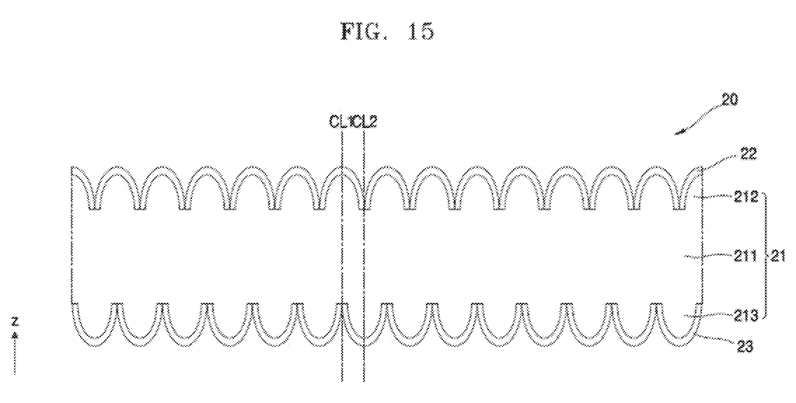

FIG. 15 is a cross-sectional view of the coating element 20 according to an embodiment.

Referring to FIG. 15, the first protrusion pattern 212 and the second protrusion pattern 213 may not be the same as each other. FIG. 15 illustrates an embodiment in which respective arrangements of the first protrusion pattern 212 and the second protrusion pattern 213 are not identical. According to an embodiment, a first center line CL1 that passes through the peak of a parabola of the first protrusion pattern 212 is defined. According to an embodiment, a second center line CL2 that passes through the peak of a parabola of the second protrusion pattern 213 is defined. According to an embodiment, the first center line CL1 and the second center line CL2 may be misaligned with each other. In embodiments, the first protrusion pattern 212 and the second protrusion pattern 213 may be misaligned with each other. According to an embodiment, the first center line CL1 and the second center line CL2 may coincide with each other. This embodiment is shown in FIG. 9.

FIG. 15 illustrates an embodiment in which the first protrusion pattern 212 and the second protrusion pattern 213 have a same shape and dimensions (e.g., as each other) but different arrangements. In embodiments, the first protrusion pattern 212 and the second protrusion pattern 213 may have different shapes, different dimensions, and/or different configurations.

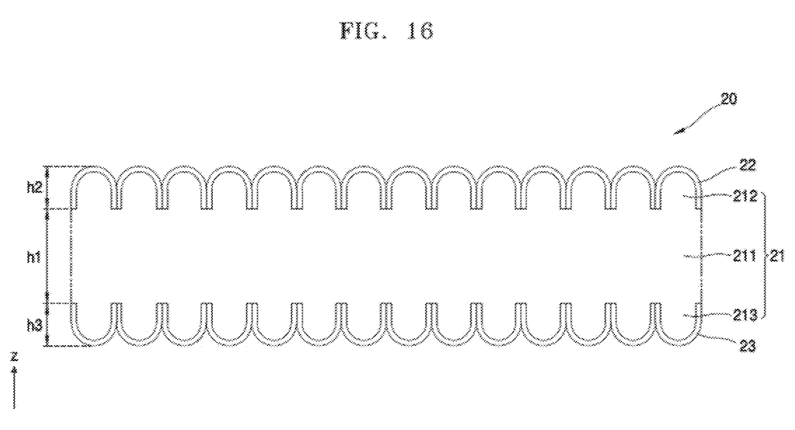

FIG. 16 is a cross-sectional view of the coating element 20 according to an embodiment.

Referring to FIG. 16, a first protrusion pattern 212 and a second protrusion pattern 213 may include a curved portion and a straight portion.

According to an embodiment, the first protrusion pattern 212 may include a straight portion extending along the z-axis direction and a curved portion on the straight portion. According to an embodiment, the curved portion of the first protrusion pattern 212 may be provided as a parabola.

According to an embodiment, a ratio between a radius of curvature of a rounded portion (e.g., the curved portion) of the first protrusion pattern 212 and a height (e.g., the second height h2) of the first protrusion pattern 212 may be defined as a 'parabolic rate' of the first protrusion pattern 212. According to an embodiment, the parabolic rate may be defined as occupancy of the curved portion (or a parabolic portion) in the first protrusion pattern 212. According to an embodiment, the parabolic rate may be defined as a parameter representing the degree of curvature, e.g., the degree of roundness, of the first protrusion pattern 212.

According to an embodiment, if (e.g., when) the first protrusion pattern 212 has a shape including only straight lines (e.g., a rectangle), the parabolic rate of the first protrusion pattern 212 may be 0%. According to an embodiment, if (e.g., when) the radius of curvature of the first protrusion pattern 212 is the same as the height (e.g., the second height h2) of the first protrusion pattern 212, the parabolic rate of the first protrusion pattern 212 may be about 100%. According to an embodiment, the parabolic rate of the first protrusion pattern 212 may be about 20% to about 100%. According to an embodiment, the parabolic rate of the first protrusion pattern 212 may be about 40% to about 100%. According to an embodiment, the first protrusion pattern 212 of the embodiment illustrated in FIG. 16 may have a parabolic rate of about 50%.

In embodiments, the second protrusion pattern 213 may include a straight portion extending along the z-axis direction and a curved portion on the straight portion. According to an embodiment, the curved portion of the second protrusion pattern 213 may be provided as a parabola.

According to an embodiment, a ratio between a radius of curvature of a rounded portion (e.g., the curved portion) of the second protrusion pattern 213 and a height (e.g., the third height h3) of the second protrusion pattern 213 may be defined as a parabolic rate of the second protrusion pattern 213. According to an embodiment, the parabolic rate may be defined as occupancy of the curved portion (or a parabolic portion) in the second protrusion pattern 213. According to an embodiment, the parabolic rate may be defined as a parameter representing the degree of curvature, e.g., the degree of roundness, of the second protrusion pattern 213.

According to an embodiment, if (e.g., when) the second protrusion pattern 213 has a shape including only straight lines (e.g., a rectangle), the parabolic rate of the second protrusion pattern 213 may be 0%. According to an embodiment, if (e.g., when) the radius of curvature of the second protrusion pattern 213 is the same as the height (e.g., the third height h3) of the second protrusion pattern 213, the parabolic rate of the second protrusion pattern 213 may be 100%. According to an embodiment, the parabolic rate of the second protrusion pattern 213 may be about 20% to about 100%. According to an embodiment, the parabolic rate of the second protrusion pattern 213 may be about 40% to about 100%. According to an embodiment, the second protrusion pattern 213 of the embodiment illustrated in FIG. 16 may have a parabolic rate of about 50%. According to an embodiment, the parabolic rate of the first protrusion pattern 212 and the parabolic rate of the second protrusion pattern 213 may be equal to each other.

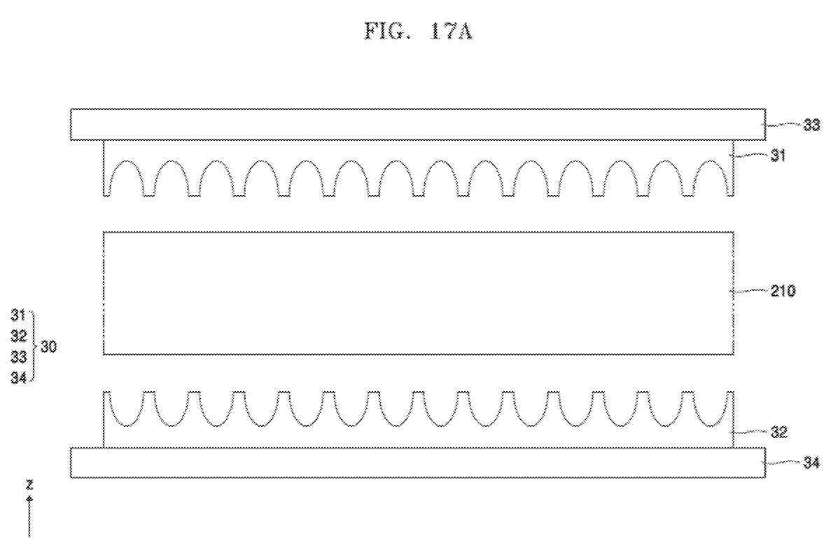

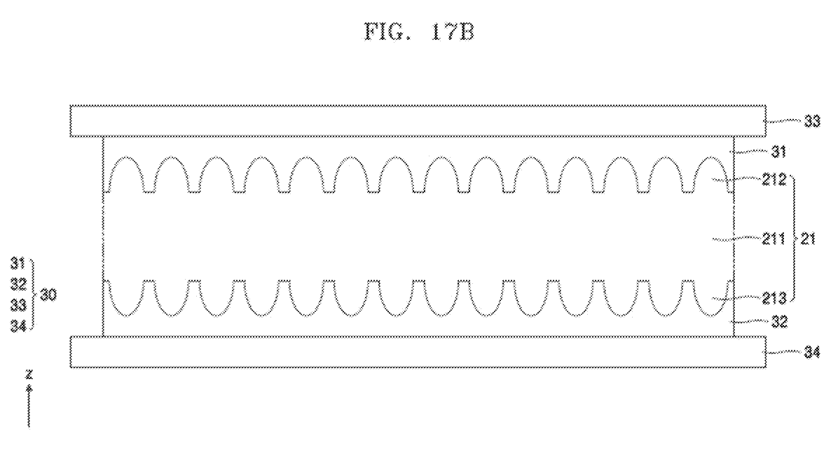

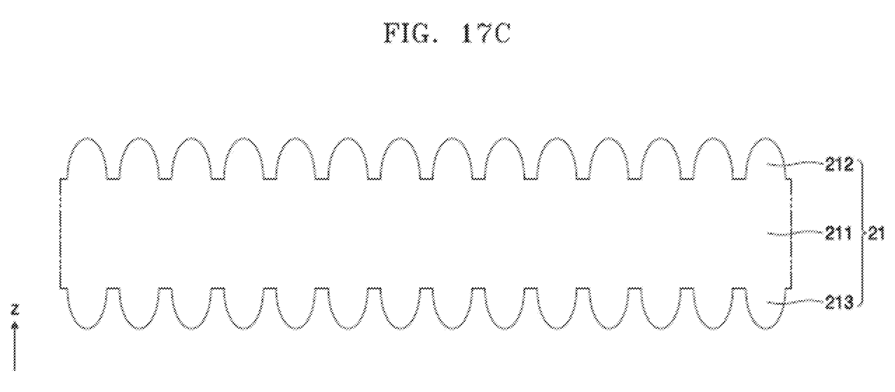

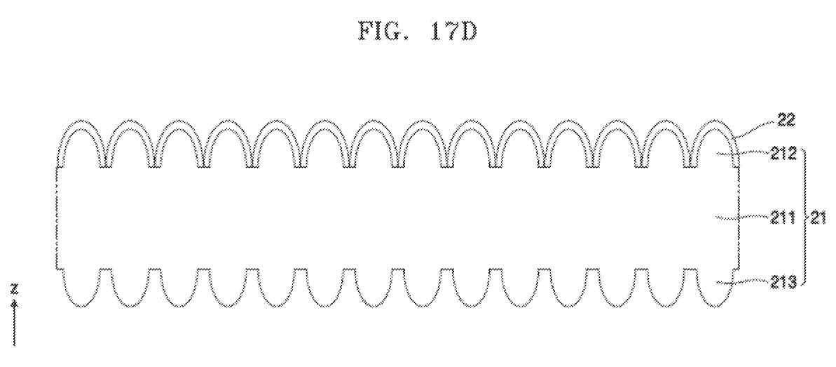

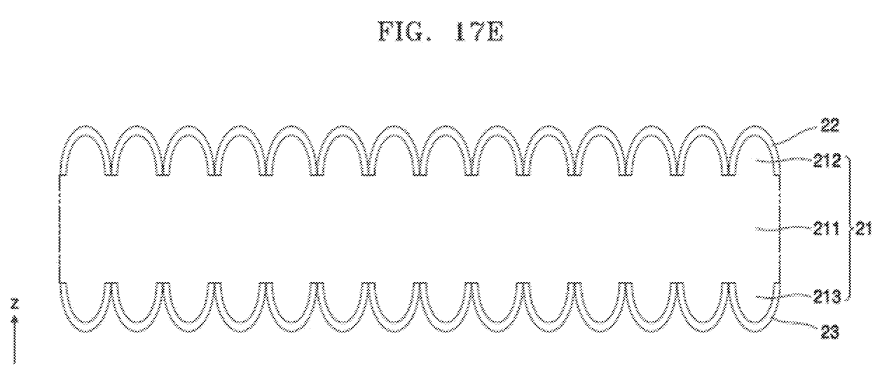

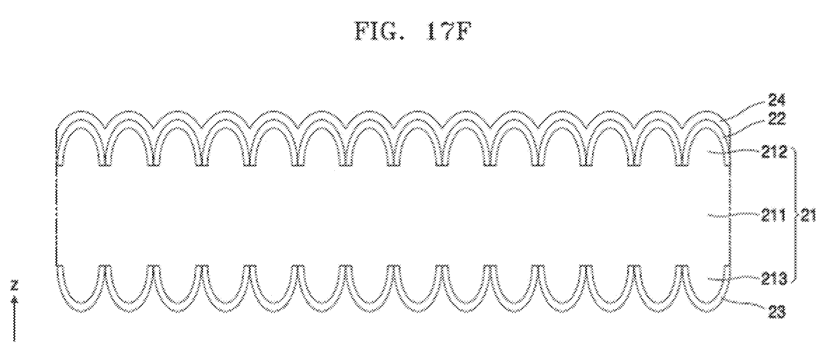

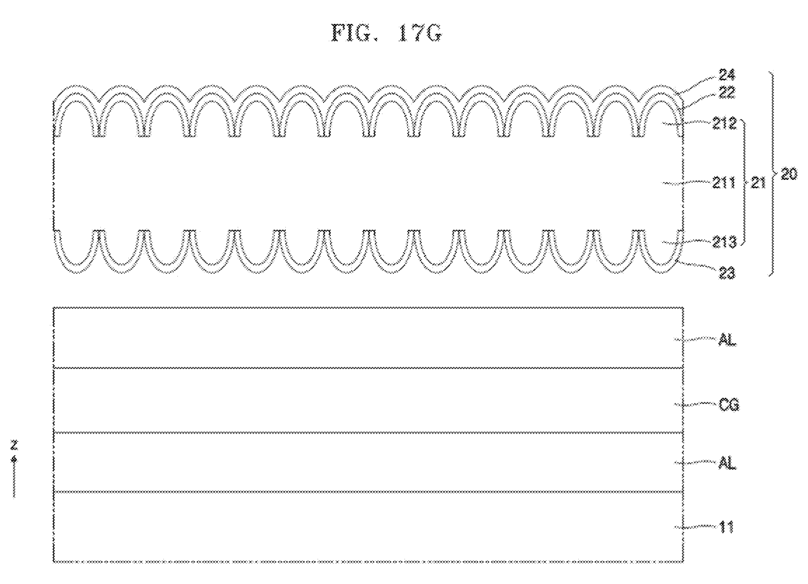

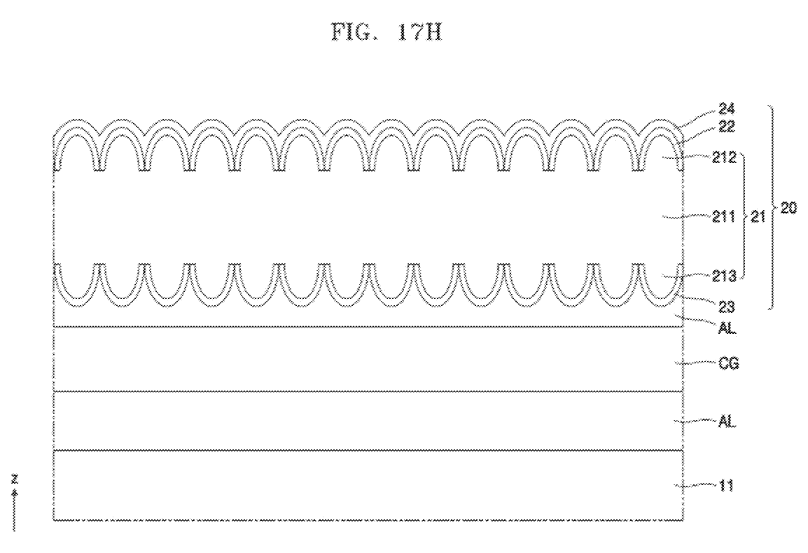

FIGS. 17A-17H are cross-sectional views illustrating a method of manufacturing an electronic device, according to an embodiment.

The method for manufacturing an electronic device may include forming the coating element 20 (see FIGS. 17A-17F) and combining the coating element 20 with the display panel 11 (see FIGS. 17G and 17H).

Referring to FIGS. 17A and 17B, the forming of the coating element 20 may include molding.

Referring to FIG. 17A, a film base 210 may be provided within a molding device 30. According to an embodiment, the film base 210 may correspond to a pre-molded state of the above-described cover film 21. Accordingly, the film base 210 may include the same material as that included in the cover film 21.

According to an embodiment, the molding device 30 may include a first mold 31, a second mold 32, a first hot plate 33, and a second hot plate 34. The first mold 31 and the second mold 32 may each include protrusions to form the film base 210 in a set or certain shape and recesses between adjacent protrusions. The first mold 31 and the second mold 32 may face each other such that the protrusions and/or the recesses of the first mold 31 face the protrusions and/or the recesses of the second mold 32. According to an embodiment, the film base 210 may be between the first mold 31 and the second mold 32.

According to an embodiment, the first hot plate 33 may be connected to the first mold 31. According to an embodiment, the first hot plate 33 may increase a temperature of the first mold 31 by transmitting heat to the first mold 31. According to an embodiment, the second hot plate 34 may be connected to the second mold 32. According to an embodiment, the second hot plate 34 may increase a temperature of the second mold 32 by transmitting heat to the second mold 32.

Referring to FIGS. 17A and 17B, the cover film 21 may be formed by pressing the film base 210 by using the molding device 30. A portion of the film base 210 deformed by the molding device 30 may be understood as the first protrusion pattern 212 and the second protrusion pattern 213, and another portion of the film base 210 that is not deformed may be understood as the main body 211.

According to an embodiment, the first mold 31 may be lowered to press against the first surface (e.g., the upper surface) of the film base 210. The film base 210, for example, the first surface of the film base 210, may be deformed by the first mold 31. According to an embodiment, a portion of the film base 210 may be recessed by the protrusions provided in the first mold 31. At the same time (or substantially the same time), another portion of the film base 210 may protrude and fill the recesses between the protrusions of the first mold 31. Accordingly, the first protrusion pattern 212 of the cover film 21 may be formed.

According to an embodiment, the first mold 31 may have a shape to form the first protrusion pattern 212. According to an embodiment, the shape of the first mold 31 may be provided in consideration of a process margin. For example, to form the first protrusion pattern 212 having a filling rate of about 90%, a corresponding shape of the first mold 31 may be provided to have a filling rate of about 70% to about 80%.

According to an embodiment, if (e.g., when) the first mold 31 presses the film base 210, the first hot plate 33 may heat the first mold 31. If (e.g., when) the first mold 31 has a suitably or sufficiently high temperature, the first surface of the film base 210 in contact with the first mold 31 may also be heated. According to an embodiment, the film base 210 may have thermoplastic properties, and moldability may be improved as the first surface of the film base 210 is heated through the first hot plate 33 and the first mold 31. Accordingly, less force may be required or utilized to shape the film base 210 to form the first protrusion pattern 212.

According to an embodiment, the second mold 32 may be raised to press against a second surface (e.g., a lower surface) of the film base 210. The film base 210, for example, the second surface of the film base 210, may be deformed by the second mold 32. According to an embodiment, a portion of the film base 210 may be recessed by the protrusions provided in the second mold 32. At the same time (or substantially the same time), another portion of the film base 210 may protrude and fill the recesses between the protrusions of the second mold 32. Accordingly, the second protrusion pattern 213 of the cover film 21 may be formed.

According to an embodiment, the second mold 32 may have a shape to form the second protrusion pattern 213. According to an embodiment, the shape of the second mold 32 may be provided in consideration of a process margin. For example, to form the second protrusion pattern 213 having a filling rate of about 90%, a corresponding shape of the second mold 32 may be provided to have a filling rate of about 70% to about 80%.

According to an embodiment, if (e.g., when) the second mold 32 presses the film base 210, the second hot plate 34 may heat the second mold 32. If (e.g., when) the second mold 32 has a suitably or sufficiently high temperature, the second surface of the film base 210 in contact with the second mold 32 may also be heated. According to an embodiment, the film base 210 may have thermoplastic properties, and moldability may be improved as the second surface of the film base 210 is heated through the second hot plate 34 and the second mold 32. Accordingly, less force may be required or utilized to shape the film base 210 to form the second protrusion pattern 213.

According to an embodiment, the forming of the first protrusion pattern 212 by using the first mold 31 and the forming of the second protrusion pattern 213 by using the second mold 32 may be performed substantially simultaneously. According to an embodiment, if (e.g., when) the first protrusion pattern 212 and the second protrusion pattern 213 have the same shape and/or arrangement (e.g., as each other), the first mold 31 and the second mold 32 may have protrusions of the same shape and/or arrangement (e.g., as each other). According to an embodiment, if (e.g., when) the first protrusion pattern 212 and the second protrusion pattern 213 have different shapes and/or arrangements, the first mold 31 and the second mold 32 may have protrusions of different shapes and/or arrangements, and temperatures of the first hot plate 33 and the second hot plate 34 may be different.

Referring to FIGS. 17B and 17C, the cover film 21 in which the first protrusion pattern 212 and the second protrusion pattern 213 are formed may be removed from the molding device 30.

Referring to FIG. 17D, the first coating 22 may be formed on the first protrusion pattern 212 of the cover film 21. According to an embodiment, the first coating 22 may be formed by atomic layer deposition (ALD). In embodiments, the forming of the first coating 22 may include ALD. Due to the forming of the first coating 22 via ALD, the first coating 22 may be formed to correspond to the shape of the first protrusion pattern 212. In embodiments, the first coating 22 may be formed via ALD to have irregularities corresponding to the first protrusion pattern 212. The disclosure, however, is not necessarily limited to the method of forming the first coating 22 through ALD. According to another embodiment, any other suitable method capable of forming the first coating 22 to correspond to the shape of the first protrusion pattern 212 while entirely covering the first protrusion pattern 212 may be considered.

Referring to FIG. 17E, the second coating 23 may be formed on the second protrusion pattern 213 of the cover film 21. According to an embodiment, the second coating 23 may be formed by chemical vapor deposition (CVD). In embodiments, the forming of the second coating 23 may include CVD. Due to the forming of the second coating 23 via CVD, the second coating 23 may be formed to correspond to the shape of the second protrusion pattern 213. In embodiments, the second coating 23 may be formed via CVD to have irregularities corresponding to the second protrusion pattern 213. The disclosure, however, is not necessarily limited to the method of forming the second coating 23 through CVD. According to another embodiment, any other suitable method capable of forming the second coating 23 to correspond to the shape of the second protrusion pattern 213 while entirely covering the second protrusion pattern 213 may be considered. According to an embodiment, the first coating 22 may be formed via CVD and the second coating 23 may be formed via ALD.

Referring to FIG. 17F, the third coating 24 may be formed on the first coating 22. According to an embodiment, the third coating 24 may include a different material from that included in the first coating 22. According to an embodiment, the third coating 24 may be formed via any suitable method, such as ALD, CVD, and/or physical vapor deposition (PVD). According to an embodiment, the third coating 24 may be formed to have the irregularities corresponding to the first coating 22 and the first protrusion pattern 212, or may be formed as a planarization layer.

Referring to FIG. 17G, the coating element 20 provided with the cover film 21, the first coating 22, the second coating 23, and the third coating 24, and the display panel 11 may be prepared. According to an embodiment, a cover glass CG may be attached onto the display panel 11. According to an embodiment, the adhesive layer AL may be formed on the cover glass CG.

Referring to FIG. 17H, the coating element 20, the cover glass CG, and the display panel 11 may be combined with each other. According to an embodiment, the coating element 20, the cover glass CG, and the display panel 11 may be pressed against each other. According to an embodiment, a portion of the adhesive layer AL may be deformed by the irregularities of the first protrusion pattern 212 and the first coating 22 of the coating element 20. A relationship (e.g., a refractive index relationship) between the adhesive layer AL, the second coating 23, and the second protrusion pattern 213 is as described above.

According to an embodiment, an electronic device including a structure between a cover film and an adhesive layer to mitigate interfacial reflection caused due to a sudden change in refractive index at an interface between the cover film and the adhesive layer is provided. According to an embodiment, an electronic device is provided having a structure capable of mitigating interfacial reflection caused due to a sudden change in refractive index between the air and a cover film in a region in contact with the outside air. According to an embodiment, an electronic device is provided having a structure capable of supplementing or improving hardness of a cover film having the structure in the region in contact with the outside air.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims, and equivalents thereof.

What is claimed is:

1. An electronic device comprising:
a display panel comprising a light-emitting diode;
a cover film on the display panel and comprising a first protrusion pattern on a first surface and a second protrusion pattern on a second surface opposite to the first surface;
a first coating on the first surface of the cover film in accordance with a shape of the first protrusion pattern; and
a second coating on the second surface of the cover film in accordance with a shape of the second protrusion pattern.

2. The electronic device of claim 1, further comprising a third coating on the first coating and comprising a different material from a material of the first coating.

3. The electronic device of claim 1, further comprising an adhesive layer between the display panel and the second coating, wherein a refractive index of the second coating is between a refractive index of the cover film and a refractive index of the adhesive layer.

4. The electronic device of claim 1, wherein the first coating has a thickness of 30 nanometers to 50 nanometers.

5. The electronic device of claim 1, wherein the second coating has a thickness of 20 nanometers to 50 nanometers.

6. The electronic device of claim 1, wherein at least one selected from the first protrusion pattern and the second protrusion pattern has a height of 200 nanometers to 400 nanometers.

7. The electronic device of claim 1, wherein the cover film has a thickness of 50 micrometers to 200 micrometers.

8. The electronic device of claim 1, wherein, in a cross-section, at least one selected from the first protrusion pattern and the second protrusion pattern has a plurality of parabolas.

9. The electronic device of claim 8, wherein a width of a lowermost portion of a first parabola among the plurality of parabolas is 40% to 100% of a distance between a peak of the first parabola and a peak of a second parabola adjacent to the first parabola.

10. The electronic device of claim 1, wherein the first protrusion pattern and the second protrusion pattern have a same shape.

11. An electronic device comprising:
a display panel comprising a light-emitting diode;
a cover film on the display panel;
a first coating on the cover film;
a second coating between the cover film and the display panel; and
an adhesive layer between the second coating and the display panel, wherein a refractive index of the second coating is between a refractive index of the cover film and a refractive index of the adhesive layer.

12. A method of manufacturing an electronic device, the method comprising:
forming a coating element; and
combining the coating element with a display panel comprising a light-emitting diode,
wherein the forming of the coating element comprises:
forming a first protrusion pattern on a first surface of a cover film;
forming a second protrusion pattern on a second surface opposite to the first surface of the cover film;
forming a first coating on the first surface of the cover film, the first coating having a shape corresponding to the first protrusion pattern; and
forming a second coating on the second surface of the cover film, the second coating having a shape corresponding to the second protrusion pattern.

13. The method of claim 12, further comprising forming a third coating on the first coating, the third coating comprising a different material from a material of the first coating.

14. The method of claim 12, wherein at least one selected from the forming of the first protrusion pattern and the forming of the second protrusion pattern comprises molding.

15. The method of claim 12, wherein the forming of the first protrusion pattern and the forming of the second protrusion pattern are performed simultaneously.

16. The method of claim 12, wherein the forming of the first coating comprises performing atomic layer deposition, and the forming of the second coating comprises performing chemical vapor deposition.

17. The method of claim 12, wherein the combining of the display panel with the coating element comprises providing an adhesive layer between the display panel and the second coating, and a refractive index of the second coating is between a refractive index of the cover film and a refractive index of the adhesive layer.

18. The method of claim 12, wherein, in a cross-section, at least one selected from the first protrusion pattern and the second protrusion pattern has a plurality of parabolas.

19. The method of claim 18, wherein a width of a lowermost portion of a first parabola among the plurality of parabolas is 40% to 100% of a distance between a peak of the first parabola and a peak of a second parabola adjacent to the first parabola.

20. The method of claim 18, wherein at least one selected from the plurality of parabolas has a height of 200 nanometers to 400 nanometers.
